(19) United States
(12) Patent Application Publication
(10) Pub. No.: US 2026/0369334 A1
(43) Pub. Date: Nov. 19, 2026

(54) PROGRAMMING AND VERIFICATION OF DIFFERENTIAL WEIGHTS IN AN ARRAY OF NON-VOLATILE MEMORY CELLS

(71) Applicant: Silicon Storage Technology, Inc., San Jose, CA (US)

(72) Inventors: Hieu Van Tran, San Jose, CA (US); Hoa Vu, San Jose, CA (US); Thuan Vu, San Jose, CA (US); Stephen Trinh, San Jose, CA (US); Louisa Schneider, San Jose, CA (US); Steven Lemke, San Jose, CA (US)

(21) Appl. No.: 19/286,094

(22) Filed: Jul. 30, 2025

Related U.S. Application Data
(60) Provisional application No. 63/805,469, filed on May 14, 2025.

(51) Int. Cl. G11C 16/34; G11C 16/10; G11C 16/32; H03M 1/06

(52) U.S. Cl. CPC G11C 16/3459; G11C 16/102; G11C 16/32; H03M 1/0604

(57) ABSTRACT

In one example, a circuit comprises a first circuit coupled to a first non-volatile memory cell to generate a first voltage in response to a first value stored in the first non-volatile memory cell; a second circuit coupled to a second non-volatile memory cell to generate a second voltage in response to a second value stored in the second non-volatile memory cell; a differential analog-to-digital converter to generate a digital value in response to a difference between the first voltage and the second voltage; and a comparator to determine whether the digital value is near a target value within a threshold.

### PRIORITY CLAIM

This application claims priority to U.S. Provisional Patent Application No. 63/805,469, filed on May 14, 2025, and titled, “Programming and Verification of Differential Weights in an Array of Non-Volatile Memory Cells,” which is incorporated by reference herein.

### FIELD OF THE INVENTION

Numerous examples are disclosed of program and verification algorithms and circuits for storing and verifying differential weights in pairs of non-volatile memory cells.

### BACKGROUND OF THE INVENTION

Artificial neural networks mimic biological neural networks (the central nervous systems of animals, in particular the brain) and are used to estimate or approximate functions that can depend on a large number of inputs and are generally unknown. Artificial neural networks generally include layers of interconnected “neurons” which exchange messages between each other.

FIG. 1 illustrates an artificial neural network, where the circles represent the inputs or layers of neurons. The connections (called synapses) are represented by arrows and have numeric weights that can be tuned based on experience. This makes neural networks adaptive to inputs and capable of learning. Typically, neural networks include a layer of multiple inputs. There are typically one or more intermediate layers of neurons, and an output layer of neurons that provide the output of the neural network. The neurons at each level individually or collectively make a decision based on the received data from the synapses.

One of the major challenges in the development of artificial neural networks for high-performance information processing is a lack of adequate hardware technology. Indeed, practical neural networks rely on a very large number of synapses, enabling high connectivity between neurons, i.e., a very high computational parallelism. In principle, such complexity can be achieved with digital supercomputers or graphics processing unit clusters. However, in addition to high cost, these approaches also suffer from mediocre energy efficiency as compared to biological networks, which consume much less energy primarily because they perform low-precision analog computation. CMOS analog circuits have been used for artificial neural networks, but most CMOS-implemented synapses have been too bulky given the high number of neurons and synapses.

Applicant previously disclosed an artificial (analog) neural network that utilizes one or more non-volatile memory arrays as the synapses in U.S. Patent Application Publication 2017/0337466A1, which is incorporated by reference. The non-volatile memory arrays operate as an analog neural memory and comprise non-volatile memory cells arranged in rows and columns. The neural network includes a first plurality of synapses configured to receive a first plurality of inputs and to generate therefrom a first plurality of outputs, and a first plurality of neurons configured to receive the first plurality of outputs. The first plurality of synapses includes a plurality of memory cells, wherein each of the memory cells includes spaced apart source and drain regions formed in a semiconductor substrate with a channel region extending therebetween, a floating gate disposed over and insulated from a first portion of the channel region and a non-floating gate disposed over and insulated from a second portion of the channel region. Each of the plurality of memory cells stores a weight value corresponding to a number of electrons on the floating gate. The plurality of memory cells multiplies the first plurality of inputs by the stored weight values to generate the first plurality of outputs.

### Non-Volatile Memory Cells

Non-volatile memories are well known. For example, U.S. Pat. No. 5,029,130 (“the '130 patent”), which is incorporated herein by reference, discloses an array of split gate non-volatile memory cells, which are a type of flash memory cells. Such a memory cell 210 is shown in FIG. 2. Each memory cell 210 includes source region 14 and drain region 16 formed in semiconductor substrate 12, with channel region 18 therebetween. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 210 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 210 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 210 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 210 for performing read, erase, and program operations:

TABLE No 1
Operation of Flash Memory Cell 210 of FIG. 2

| | WL | | BL | | SL | |
|---|---|---|---|---|---|---|
| Read | 2-3 | V | 0.6-2 | V | 0 | V |
| Erase | ~11-13 | V | 0 | V | 0 | V |
| Program | 1-2 | V | 10.5-3 | μA | 9-10 | V |

Other split gate memory cell configurations, which are other types of flash memory cells, are known. For example, FIG. 3 depicts a four-gate memory cell 310 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 310 for performing read, erase, and program operations:

TABLE No 2
Operation of Flash Memory Cell 310 of FIG. 3

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |
| Erase | −0.5 V/0 | V | 0 | V | 0 V/−8 | V | 8-12 | V | 0 | V |
| Program | 1 | V | 0.1-l | μA | 8-11 | V | 4.5-9 | V | 4.5-5 | V |

FIG. 4 depicts a three-gate memory cell 410, which is another type of flash memory cell. Memory cell 410 is identical to the memory cell 310 of FIG. 3 except that memory cell 410 does not have a separate control gate. The erase operation (whereby erasing occurs through use of the erase gate) and read operation are similar to that of FIG. 3 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE No 3
Operation of Flash Memory Cell 410 of FIG. 4

| | WL/SG | | BL | | EG | | SL | |
|---|---|---|---|---|---|---|---|---|
| Read | 0.7-2.2 | V | 0.6-2 | V | 0-2.6 | V | 0 | V |
| Erase | −0.5 V/0 | V | 0 | V | 11.5 | V | 0 | V |
| Program | 1 | V | 0.2-3 | μA | 4.5 | V | 7-9 | V |

FIG. 5 depicts stacked gate memory cell 510, which is another type of flash memory cell. Memory cell 510 is similar to memory cell 210 of FIG. 2, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at the region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 510 and substrate 12 for performing read, erase, and program operations:

TABLE No 4
Operation of Flash Memory Cell 510 of FIG. 5

| | CG | | BL | | SL | | Substrate | |
|---|---|---|---|---|---|---|---|---|
| Read | 2-5 | V | 0.6-2 | V | 0 | V | 0 | V |
| Erase | −8 to −10 V/0 V | | FLT | | FLT | | 8-10 V/15-20 V | |
| Program | 8-12 | V | 3-5 | V | 0 | V | 0 | V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

In order to utilize the memory arrays comprising one of the types of non-volatile memory cells described above in an artificial neural network, two modifications are made. First, the lines are configured so that each memory cell can be individually programmed, erased, and read without adversely affecting the memory state of other memory cells in the array, as further explained below. Second, continuous (analog) programming of the memory cells is provided.

Specifically, the memory state (i.e., charge on the floating gate) of each memory cell in the array can be continuously changed from a fully erased state to a fully programmed state, and vice-versa, independently and with minimal disturbance of other memory cells. This means the cell storage is effectively analog or at the very least can store one of many discrete values (such as 16 or 64 different values), which allows for very precise and individual tuning of all the memory cells in the memory array, and which makes the memory array ideal for storing and making fine-tuning adjustments to the synapsis weights of the neural network.

### Neural Networks Employing Non-Volatile Memory Cell Arrays

FIG. 6 conceptually illustrates a non-limiting example of a neural network utilizing a non-volatile memory array of the present examples. This example uses the non-volatile memory array neural network for a facial recognition application, but any other appropriate application could be implemented using a non-volatile memory array based neural network. A non-volatile memory array and associated circuitry used in a neural network is one type of computation-in-memory (CIM) engine or vector-by-matrix (VMM) multiplication system.

S0 is the input layer, which for this example is a 32×32 pixel RGB image with 5-bit precision (i.e., three 32×32 pixel arrays, one for each color R, G, and B, each pixel being 5-bit precision). The synapses CB1 going from input layer SO to layer C1 apply different sets of weights in some instances and shared weights in other instances and scan the input image with 3×3 pixel overlapping filters (kernel), shifting the filter by 1 pixel (or more than 1 pixel as dictated by the model). Specifically, values for 9 pixels in a 3×3 portion of the image (i.e., referred to as a filter or kernel) are provided to the synapses CB1, where these 9 input values are multiplied by the appropriate weights and, after summing the outputs of that multiplication, a single output value is determined and provided by a first synapse of CB1 for generating a pixel of one of the feature maps of layer C1. The 3×3 filter is then shifted one pixel to the right within input layer SO (i.e., adding the column of three pixels on the right, and dropping the column of three pixels on the left), whereby the 9 pixel values in this newly positioned filter are provided to the synapses CB1, where they are multiplied by the same weights and a second single output value is determined by the associated synapse. This process is continued until the 3×3 filter scans across the entire 32×32 pixel image of input layer S0, for all three colors and for all bits (precision values). The process is then repeated using different sets of weights to generate a different feature map of layer C1, until all the feature maps of layer C1 have been calculated.

In layer C1, in the present example, there are 16 feature maps, with 30×30 pixels each. Each pixel is a new feature pixel extracted from multiplying the inputs and kernel, and therefore each feature map is a two-dimensional array, and thus in this example layer C1 constitutes 16 layers of two-dimensional arrays (keeping in mind that the layers and arrays referenced herein are logical relationships that may or may not correspond to physical relationships—i.e., the arrays may or may not be oriented in physical two dimensional arrays). Each of the 16 feature maps in layer C1 is generated by one of sixteen different sets of synapse weights applied to the filter scans. The C1 feature maps could all be directed to different aspects of the same image feature, such as boundary identification. For example, the first map (generated using a first weight set, shared for all scans used to generate this first map) could identify circular edges, the second map (generated using a second weight set different from the first weight set) could identify rectangular edges, or the aspect ratio of certain features, and so on.

An activation function P1 (pooling) is applied before going from layer C1 to layer S1, which pools values from consecutive, non-overlapping 2×2 regions in each feature map. The purpose of the pooling function P1 is to average out the nearby location (or a max function can also be used), to reduce the dependence of the edge location for example and to reduce the data size before going to the next stage. At layer S1, there are 16 15×15 feature maps (i.e., sixteen different arrays of 15×15 pixels each). The synapses CB2 going from layer S1 to layer C2 scan maps in layer S1 with 4×4 filters, with a filter shift of 1 pixel. At layer C2, there are 22 12×12 feature maps. An activation function P2 (pooling) is applied before going from layer C2 to layer S2, which pools values from consecutive non-overlapping 2×2 regions in each feature map. At layer S2, there are 22 6×6 feature maps. An activation function (pooling) is applied at the synapses CB3 going from layer S2 to layer C3, where every neuron in layer C3 connects to every map in layer S2 via a respective synapse of CB3. At layer C3, there are 64 neurons. The synapses CB4 going from layer C3 to the output layer S3 fully connects C3 to S3, i.e., every neuron in layer C3 is connected to every neuron in layer S3. The output at S3 includes 10 neurons, where the highest output neuron determines the class. This output could, for example, be indicative of an identification or classification of the contents of the original image.

Each layer of synapses is implemented using an array, or a portion of an array, of non-volatile memory cells.

FIG. 7 is a block diagram of an array that can be used for that purpose. Vector-by-matrix multiplication (VMM) array 32 includes non-volatile memory cells and is utilized as the synapses (such as CB1, CB2, CB3, and CB4 in FIG. 6) between one layer and the next layer. Specifically, VMM array 32 includes an array of non-volatile memory cells 33, erase gate and word line gate decoder 34, control gate decoder 35, bit line decoder 36 and source line decoder 37, which decode the respective inputs for the non-volatile memory cell array 33. Input to VMM array 32 can be from the erase gate and wordline gate decoder 34 or from the control gate decoder 35. Source line decoder 37 in this example also decodes the output of the non-volatile memory cell array 33. Alternatively, bit line decoder 36 can decode the output of the non-volatile memory cell array 33.

Non-volatile memory cell array 33 serves two purposes. First, it stores the weights that will be used by the VMM array 32. Second, the non-volatile memory cell array 33 effectively multiplies the inputs by the weights stored in the non-volatile memory cell array 33 and adds them up per output line (source line or bit line) to produce the output, which will be the input to the next layer or input to the final layer. By performing the multiplication and addition function, the non-volatile memory cell array 33 negates the need for separate multiplication and addition logic circuits and is also power efficient due to its in-situ memory computation.

The output of non-volatile memory cell array 33 is supplied to a differential summer (such as a summing op-amp or a summing current mirror) 38, which sums up the outputs of the non-volatile memory cell array 33 to create a single value for that convolution. The differential summer 38 is arranged to perform summation of positive weight and negative weight.

The summed-up output values of differential summer 38 are then supplied to an activation function block 39, which rectifies the output. The activation function block 39 may provide sigmoid, tanh, or ReLU functions. The rectified output values of activation function block 39 become an element of a feature map as the next layer (e.g., C1 in FIG. 6), and are then applied to the next synapse to produce the next feature map layer or final layer. Therefore, in this example, non-volatile memory cell array 33 constitutes a plurality of synapses (which receive their inputs from the prior layer of neurons or from an input layer such as an image database), and summing op-amp 38 and activation function block 39 constitute a plurality of neurons.

The input to VMM array 32 in FIG. 7 (WLx, EGx, CGx, and optionally BLx and SLx) can be analog level, binary level, or digital bits (in which case a DAC is provided to convert digital bits to appropriate input analog level) and the output can be analog level, binary level, or digital bits (in which case an output ADC is provided to convert output analog level into digital bits).

FIG. 8 is a block diagram depicting the usage of numerous layers of VMM arrays 32, here labeled as VMM arrays 32a, 32b, 32c, 32d, and 32e. As shown in FIG. 8, the input, denoted Inputx, is converted from digital to analog by a digital-to-analog converter 31 and provided to input VMM array 32a. The converted analog inputs could be voltage or current. The input D/A conversion for the first layer could be done by using a function or a LUT (look up table) that maps the inputs Inputx to appropriate analog levels for the matrix multiplier of input VMM array 32a. The input conversion could also be done by an analog-to-analog (A/A) converter to convert an external analog input to a mapped analog input to the input VMM array 32a.

The output generated by input VMM array 32a is provided as an input to the next VMM array (hidden level 1) 32b, which in turn generates an output that is provided as an input to the next VMM array (hidden level 2) 32c, and so on. The various layers of VMM array 32 function as different layers of synapses and neurons of a convolutional neural network (CNN). Each VMM array 32a, 32b, 32c, 32d, and 32e can be a stand-alone, physical non-volatile memory array, or multiple VMM arrays could utilize different portions of the same physical non-volatile memory array, or multiple VMM arrays could utilize overlapping portions of the same physical non-volatile memory array. The example shown in FIG. 8 contains five layers (32a, 32b, 32c, 32d, 32e): one input layer (32a), two hidden layers (32b, 32c), and two fully connected layers (32d,32e). One of ordinary skill in the art will appreciate that this is merely an example and that a system instead could comprise more than two hidden layers and more than two fully connected layers.

### Differential Cells

In general, for each memory cell in a VMM array, each weight W can be implemented by a single memory cell or by a differential cell or by two blend memory cells (average of 2 cells). In the differential cell case, two memory cells are used to implement a weight W as a differential weight (W=W+−W−). In the two blend memory cells, two memory cells are used to implement a weight W as an average of two cells.

FIG. 9 depicts VMM system 900. In some examples, the weights, W, stored in a VMM array are stored as differential pairs, W+ (positive weight) and W− (negative weight), where W=(W+)−(W−). In VMM system 900, half of the bit lines are designated as W+ lines, that is, bit lines connecting to memory cells that will store positive weights W+, and the other half of the bit lines are designated as W− lines, that is, bit lines connecting to memory cells implementing negative weights W−. The W− lines are interspersed among the W+ lines in an alternating fashion. The subtraction operation is performed by a summation circuit that receives current from a W+ line and a W− line, such as summation circuits 901 and 902. The output of a W+ line and the output of a W− line are combined together to give effectively W=W+−W− for each pair of (W+, W−) cells for all pairs of (W+, W−) lines. While the above has been described in relation to W− lines interspersed among the W+ lines in an alternating fashion, in other examples W+ lines and W-lines can be arbitrarily located anywhere in the array.

FIG. 10 depicts another example. In VMM system 1010, positive weights W+ are implemented in first array 1011 and negative weights W− are implemented in a second array 1012, second array 1012 separate from the first array, and the resulting weights are appropriately combined together by summation circuits 1013.

Each non-volatile memory cell used in an analog neural memory system, whether as single memory cells or differential cells, is to be erased and programmed to hold a very specific and precise amount of charge in the floating gate of the cell. For example, each floating gate or pair of floating gates can hold one of N different values, where N is the number of different weights that can be indicated by each cell. Examples of N include 16, 32, 64, 128, and 256. Precision is achieved through extensive programming and verification sequences. However, prior art programming and verification sequences require significant time, often involving hundreds of separate programming and verification events.

What is needed are improved programming and verification techniques for storing differential weights in pairs of non-volatile memory cells.

### SUMMARY OF THE INVENTION

Numerous examples are disclosed of program and verification algorithms and circuits for storing and verifying differential weights in pairs of non-volatile memory cells.

In one example, a circuit comprises a first circuit coupled to a first non-volatile memory cell to generate a first voltage in response to a first value stored in the first non-volatile memory cell; a second circuit coupled to a second non-volatile memory cell to generate a second voltage in response to a second value stored in the second non-volatile memory cell; a differential analog-to-digital converter to generate a digital value in response to a difference between the first voltage and the second voltage; and a comparator to determine whether the digital value is near a target value within a threshold.

In another example, a circuit comprises a current-to-voltage converter selectively coupled to a first non-volatile memory cell during a first time period to generate a first voltage and to a second non-volatile memory cell during a second time period to generate a second voltage; and a circuit to generate a digital value in response to a difference between the first voltage and the second voltage.

In another example, a method of overshoot recovery in programming and verification of a differential pair of non-volatile memory cells comprising a first non-volatile memory cell and a second non-volatile memory cell comprises determining a target value for the differential pair of non-volatile memory cells; performing programming operations on the first non-volatile memory cell; performing programming operations on the second non-volatile memory cell; and when a difference between a value stored in the first non-volatile memory cell and a value stored in the second non-volatile memory cell is less than the target value by a threshold value, performing precision programming on the second non-volatile memory cell.

In another example, a method of programming and verification of a differential pair of non-volatile memory cells comprising a first non-volatile memory cell and a second non-volatile memory cell comprises determining a target value for the differential pair of non-volatile memory cells; performing programming operations on the first non-volatile memory cell; performing programming operations on the second non-volatile memory cell; and performing precision programming on the non-volatile memory cell storing the lower value among the first non-volatile memory cell and the second non-volatile memory cell.

In another example, a method of programming and verifying a differential value comprises programming a first non-volatile memory cell to store a first value, W+; programming a second non-volatile memory cell to store a second value, W−; and verifying that the value W is within a predetermined threshold of a target value, where W=(W+)−(W−).

In another example, a method of performing gain error compensation in a differential verify circuit, the method comprises applying a reference current to a first input of the differential verify circuit to generate a first voltage; applying the reference current to a second input of the differential verify circuit to generate a second voltage; determining a gain equal to a first value divided by a second value, wherein the first value is the second voltage minus the first voltage and the second value is the reference current; determining a gain error equal to the gain divided by a target gain; and programming a pair of non-volatile memory cells to store a differential value equal to a target weight comprising compensation for the gain error.

### BRIEF DESCRIPTION OF THE DRAWINGS

FIG. 1 is a diagram that illustrates an artificial neural network.

FIG. 2 depicts a prior art split gate flash memory cell.

FIG. 3 depicts another prior art split gate flash memory cell.

FIG. 4 depicts another prior art split gate flash memory cell.

FIG. 5 depicts another prior art split gate flash memory cell.

FIG. 6 is a diagram illustrating the different levels of an example artificial neural network utilizing one or more non-volatile memory arrays.

FIG. 7 is a block diagram illustrating a VMM system.

FIG. 8 is a block diagram illustrating an example artificial neural network utilizing one or more VMM systems.

FIG. 9 depicts another example of a VMM system.

FIG. 10 depicts another example of a VMM system.

FIG. 11 depicts a VMM system.

FIG. 12 depicts a differential verify circuit.

FIG. 13 depicts another differential verify circuit.

FIG. 14 depicts another differential verify circuit.

FIG. 15 depicts another differential verify circuit.

FIG. 16 depicts another differential verify circuit.

FIG. 17 depicts a gain error compensation method for a differential verify circuit.

FIGS. 18A and 18B depict programming and verification methods for a pair of non-volatile memory cells storing a differential weight,

FIG. 19 depicts a programming and verification method.

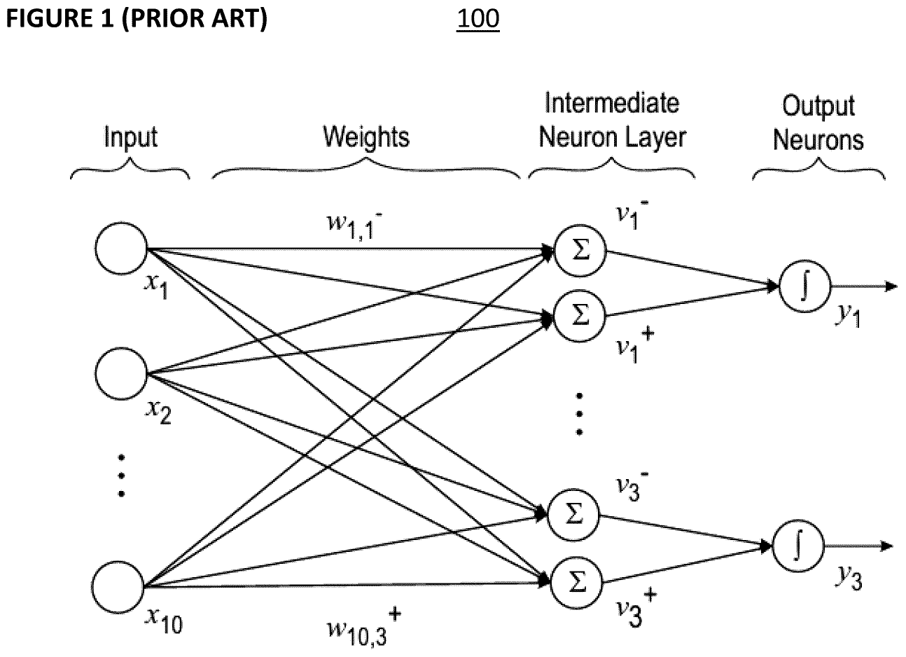

### DETAILED DESCRIPTION OF THE INVENTION

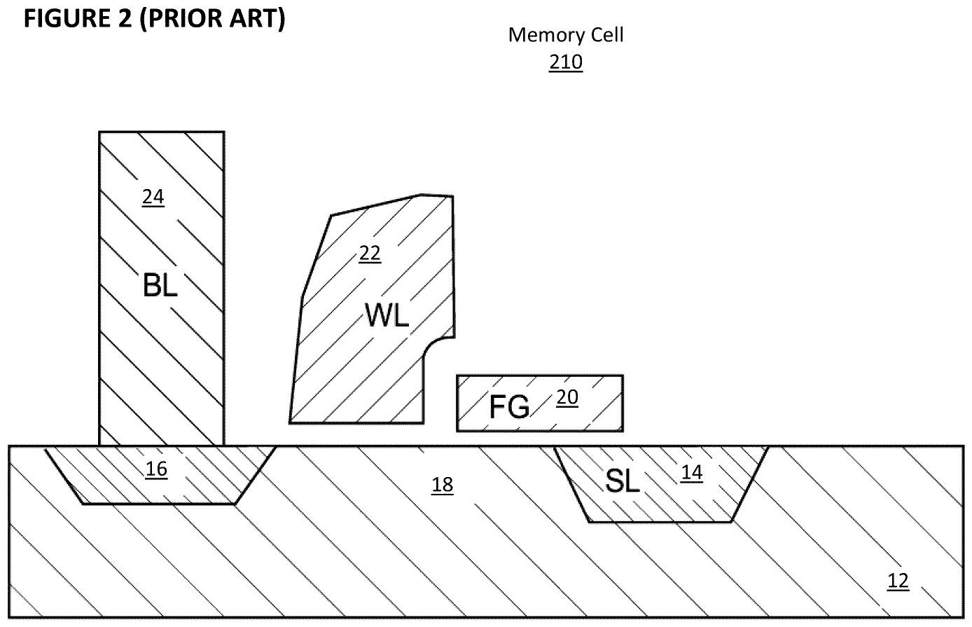

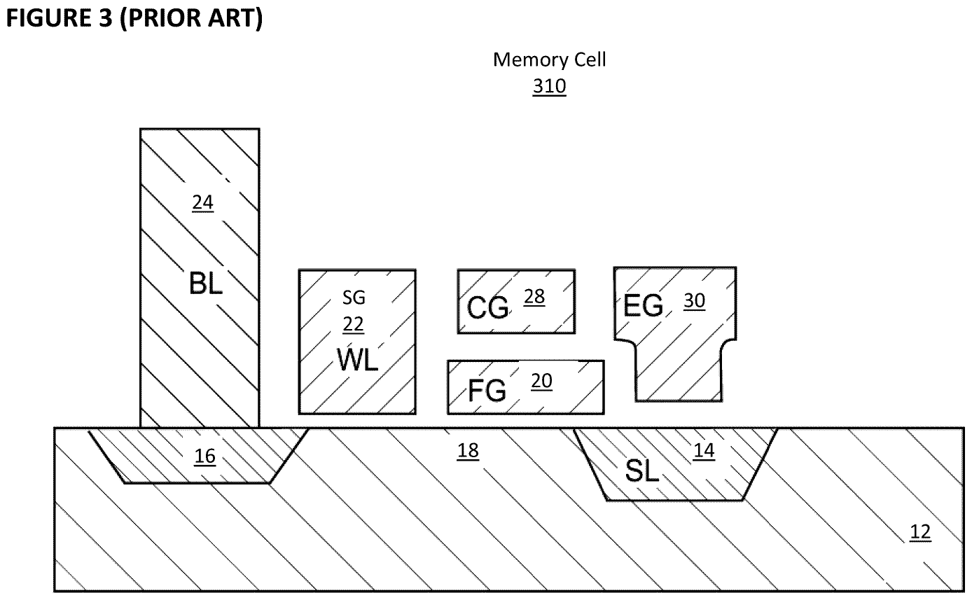

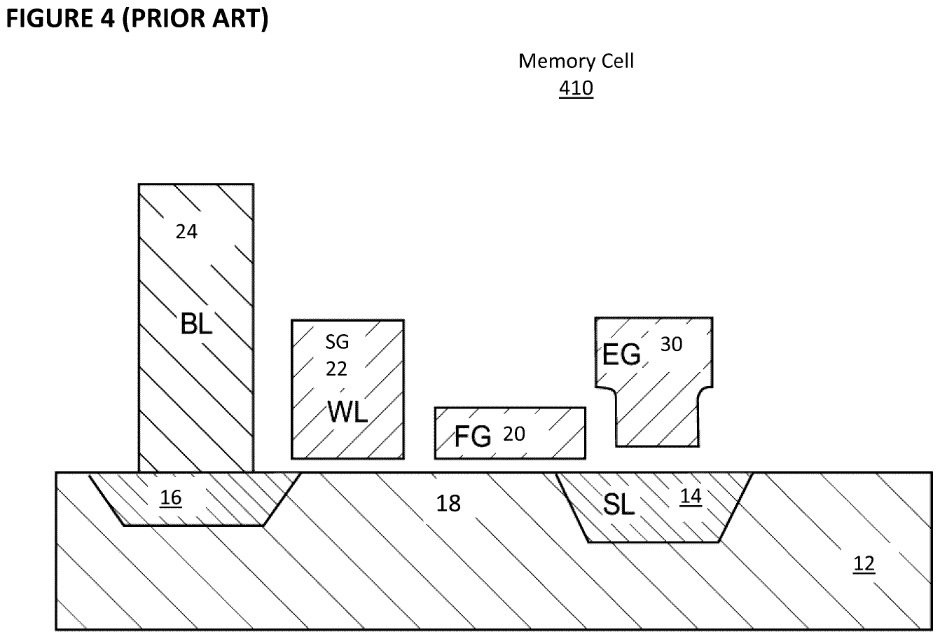

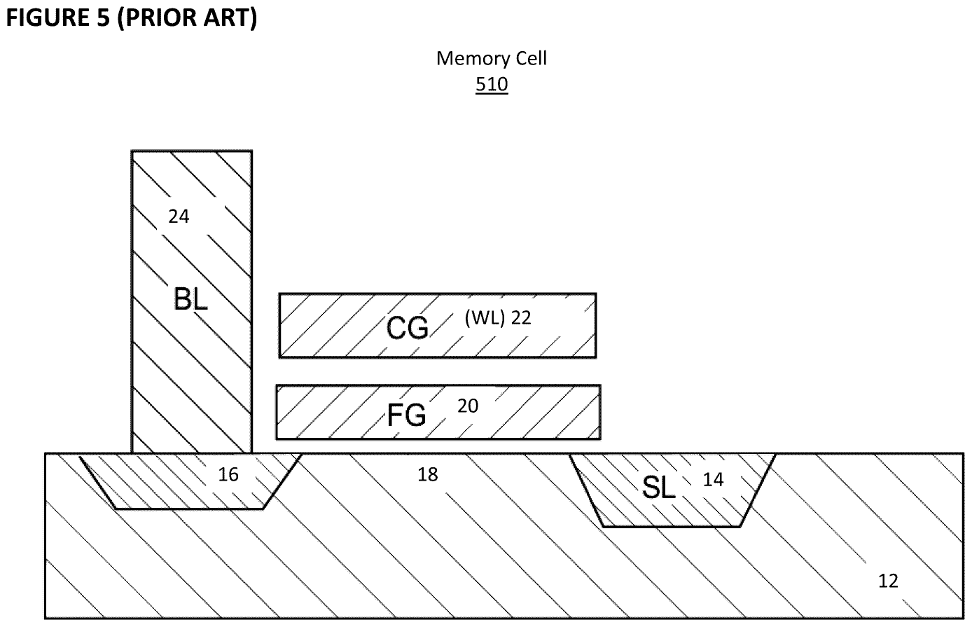

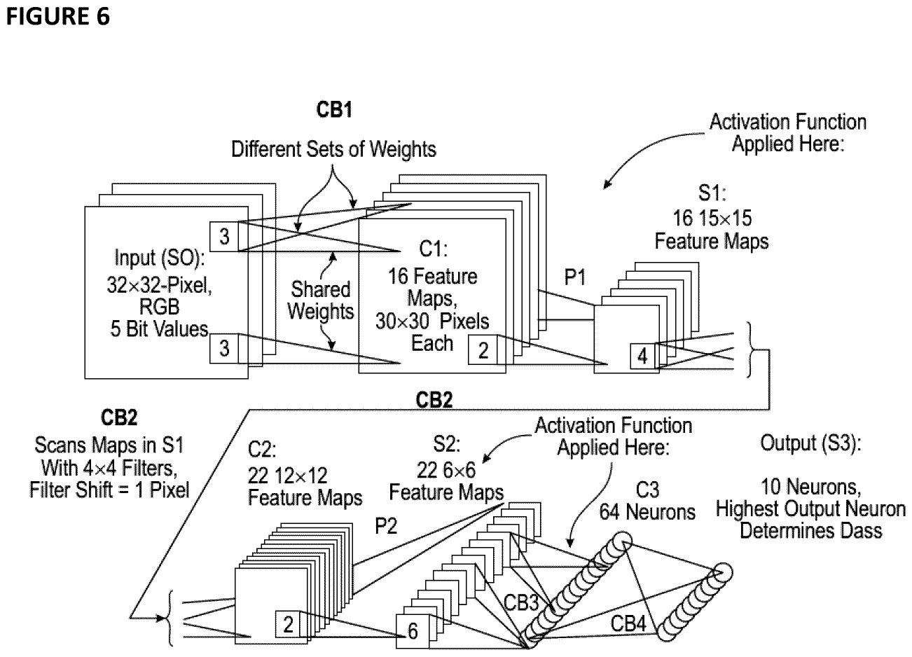

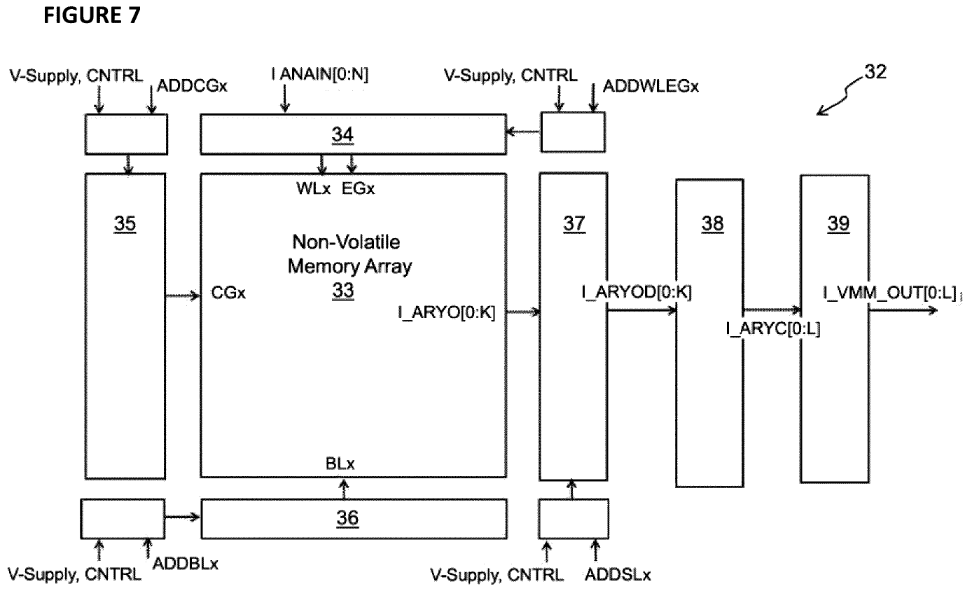

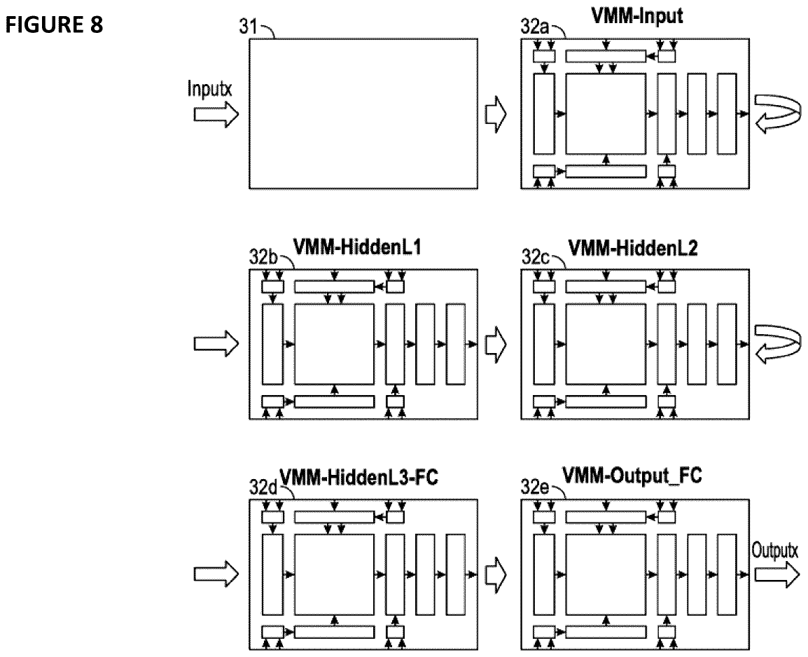

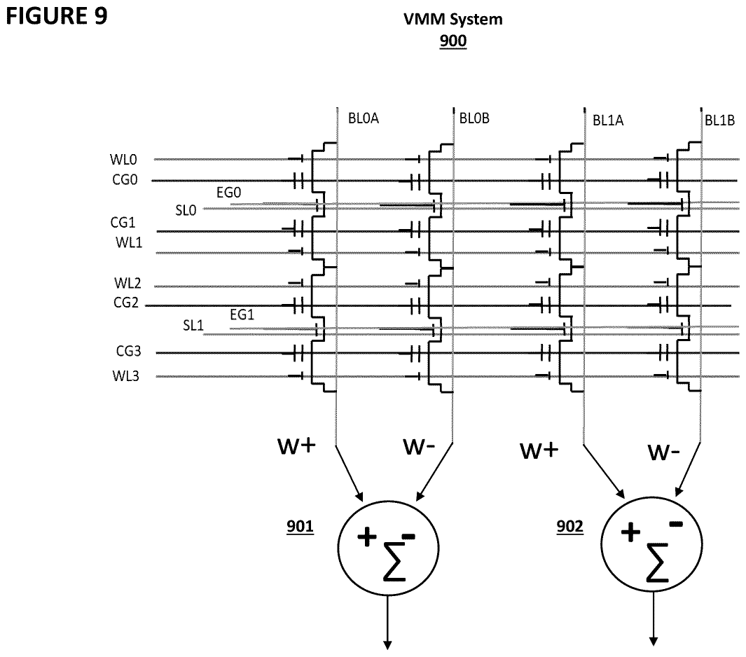

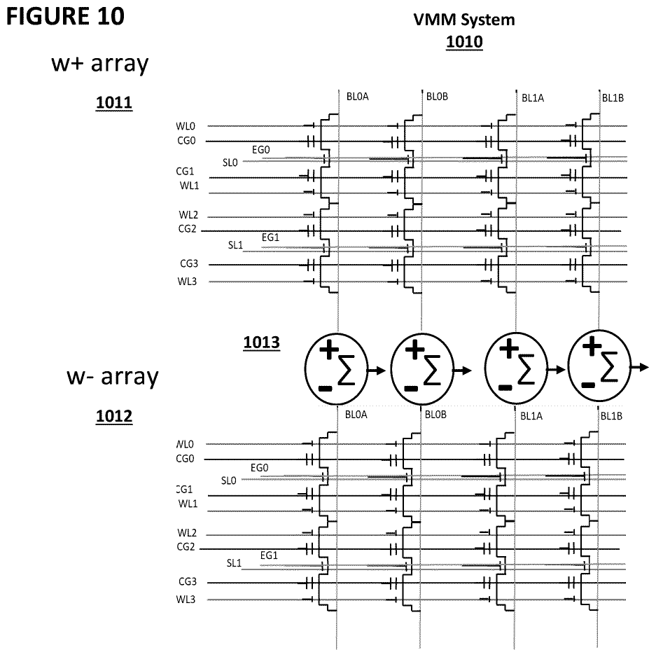

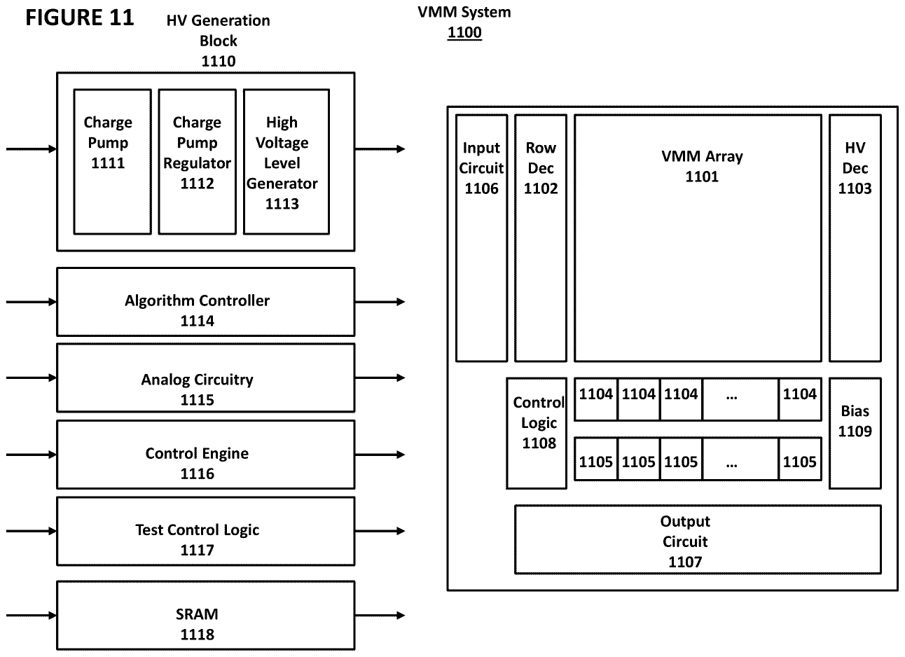

FIG. 11 depicts a block diagram of a VMM system 1100. VMM system 1100 comprises VMM array 1101, row decoder 1102, high voltage decoder 1103, column decoders 1104, bit line drivers 1105, input circuit 1106, output circuit 1107, control logic 1108, and bias generator 1109. VMM system 1100 further comprises high voltage generation block 1110, which comprises charge pump 1111, charge pump regulator 1112, and high voltage analog precision level generator 1113. VMM system 1100 further comprises (program/erase, or weight tuning) algorithm controller 1114, analog circuitry 1115, control engine 1116 (that may include functions such as arithmetic functions, activation functions, embedded microcontroller logic, without limitation), and test control logic 1117. VMM array 1101 comprises non-volatile memory cells arranged into rows and columns. The non-volatile memory cells can be split-gate flash memory cells such as of the type shown in FIGS. 2, 3, and 4 as memory cells 210, 310, 410, respectively, stacked-gate flash memory cells such as of the type shown in FIG. 5 as memory cell 510, or another type of non-volatile memory cell.

The input circuit 1106 may include circuits such as a DAC (digital to analog converter), DPC (digital to pulses converter, digital to time modulated pulse converter), AAC (analog to analog converter, such as a current to voltage converter, logarithmic converter), PAC (pulse to analog level converter), or any other type of converters. The input circuit 1106 may implement one or more of normalization, linear or non-linear up/down scaling functions, or arithmetic functions. The input circuit 1106 may implement a temperature compensation function for input levels. The input circuit 1106 may implement an activation function such as ReLU or sigmoid.

The output circuit 1107 may include circuits such as an ADC (analog to digital converter, to convert neuron analog output to digital bits), AAC (analog to analog converter, such as a current to voltage converter, logarithmic converter), APC (analog to pulse(s) converter, analog to time modulated pulse converter), or any other type of converters. The output circuit 1107 may implement an activation function such as rectified linear activation function (ReLU) or sigmoid. The output circuit 1107 may implement one or more of statistic normalization, regularization, up/down scaling/gain functions, statistical rounding, or arithmetic functions (e.g., add, subtract, divide, multiply, shift, log) for neuron outputs. The output circuit 1107 may implement a temperature compensation function for neuron outputs or array outputs (such as bitline output) so as to keep power consumption of the array approximately constant or to improve precision of the array (neuron) outputs such as by keeping the IV slope approximately the same.

In the prior art differential weight systems, a W+ cell and a W− cell would be programmed and verified separately, which is a time-consuming process. In the examples described below, a W+ cell and a W− cell are programmed and verified together, wherein the verification process compares the difference, W, in the values of W+ and W−(where W=W+−W−) against a target value rather than compare the W+ value against a first target value and the W− value against a second target value. This saves time compared to the prior art because near the end of the process precision programming needs to be performed on only one of the cells instead of both cells.

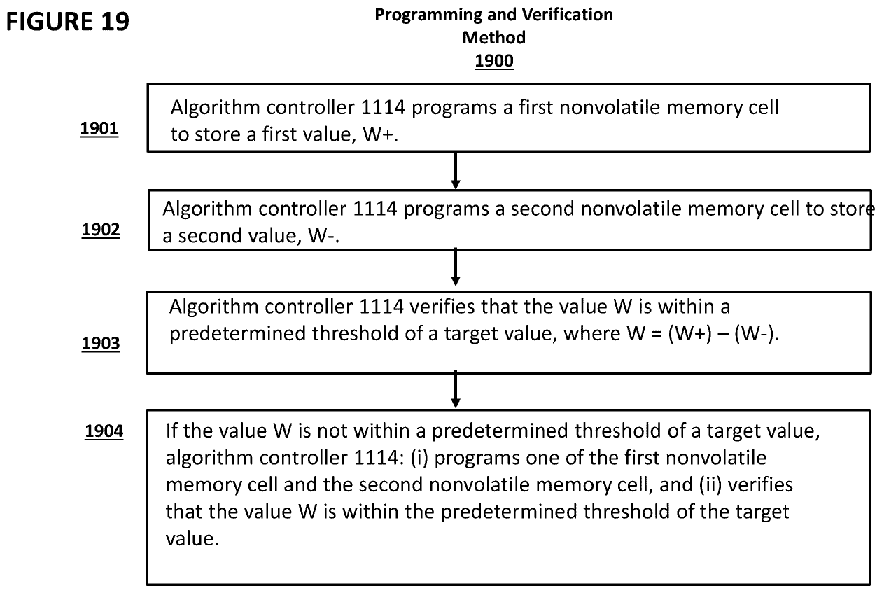

This is depicted in FIG. 19 as programming and verification method 1900, which can be performed by algorithm controller 1114 in FIG. 11.

First, algorithm controller 1114 programs a first non-volatile memory cell to store a first value, W+ (1901).

Second, algorithm controller 1114 programs a second non-volatile memory cell to store a second value, W−(1902).

Third, algorithm controller 1114 verifies that the value W is within a predetermined threshold of a target value, where W=(W+)−(W−) (1903).

Fourth, if the value W is not within a predetermined threshold of a target value, algorithm controller 1114: (i) programs one of the first non-volatile memory cell and the second non-volatile memory cell, and (ii) verifies that the value W is within the predetermined threshold of the target value (1904).

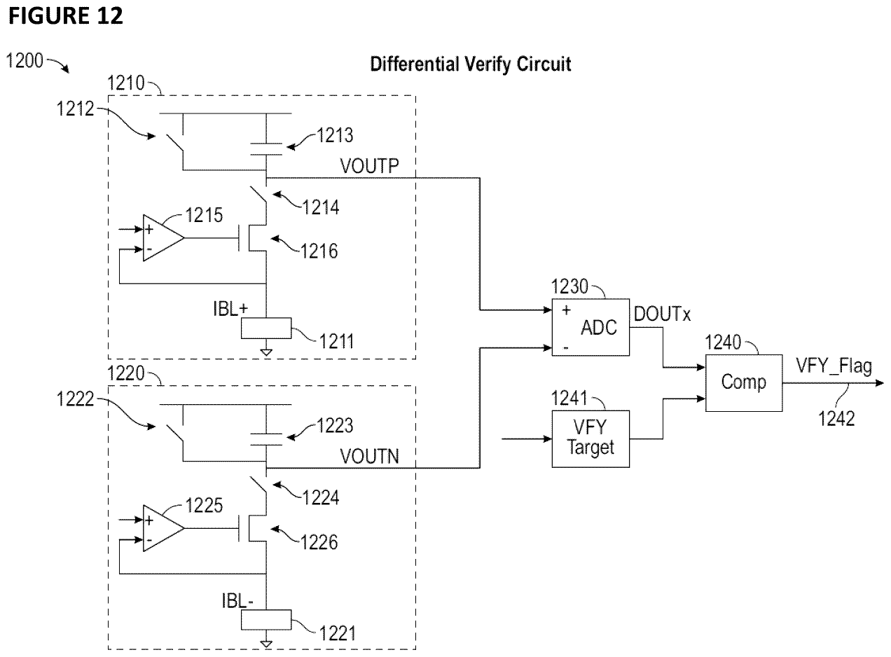

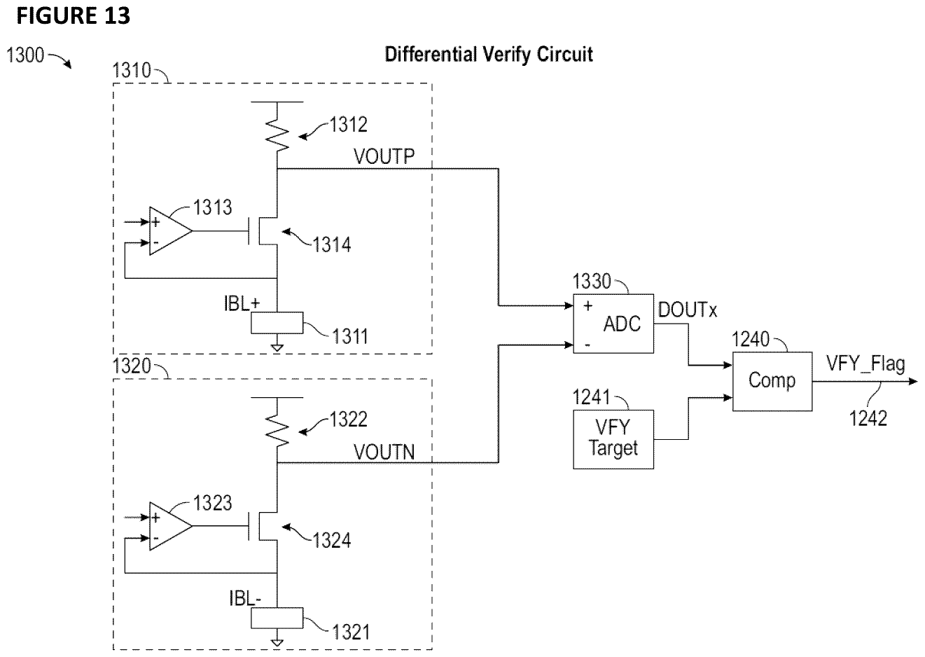

FIG. 12 depicts differential verify circuit 1200 that can be controlled by algorithm controller 1114 in FIG. 11 to perform programming and verification method 1900 in FIG. 19. Differential verify circuit 1200 comprises current-to-voltage (ITV) converter 1210 (a first circuit) coupled to W+ cell 1211, current-to-voltage (ITV) converter 1220 (a second circuit) coupled to W-cell 1221, and analog-to-digital converter (ADC) 1230. Differential verify circuit 1200 also comprises verify target circuit 1241, which stores the target value, and comparison circuit 1240, which compares the output of ADC 1230, DOUTx, against the verify target from verify target circuit 1241 to determine whether the ADC output is within an acceptable range of the target value, indicated by output 1242 (VFY_Flag), where the acceptable range can be set by a threshold value. Verify target circuit 1241 and comparison circuit 1240 also can be used in differential verify circuits 1300, 1400, 1500, and 1600 described below in FIGS. 13, 14, 15, and 16, respectively. W+ cell 1211 stores a weight W+ and W− cell 1221 stores a weight W−. Together, W+ cell 1211 and W−1 cell 1221 store a weight, W, where W=(W+)−(W−). ITV converter 1210 converts the current from W− cell 1211 into a voltage VOUTP and ITV converter 1210 converts the current from W+ cell 1221 into a voltage VOUTN. ADC 1230 converts (digitizes) the voltage difference (VOUTP− VOUTN) into a digital output, DOUTx. Hence, the value of DOUTx reflects the cell current difference between W+ cell 1211 and W− cell 1221, meaning that DOUTx=W.

ITV converter 1210 comprises switches 1212 and 1214, load capacitor 1213, operational amplifier 1215, and NMOS transistor 1216, arranged as shown. ITV converter 1220 comprises switches 1222 and 1224, load capacitor 1223, operational amplifier 1225, and NMOS transistor 1226, arranged as shown.

Prior to a read or verify operation, switches 1212 and 1222 are closed and switches 1214 and 1224 are opened, which causes the bottom terminals of capacitors 1213 and 1223 to charge to the voltage of the supply voltage. During the read or verify operation, switches 1212 and 1222 are opened and switches 1214 and 1224 are closed for an integration time, Tint. During this period Tint, W+ cell 1211 will draw a current IBL+ that will discharge capacitor 1213 to a voltage VOUTP, and W− cell 1221 will draw a current IBL− that will discharge capacitor 1224 to a voltage VOUTN, according to the equation (Vdd−VOUTx)=(Icell*Tint)/C, where Vdd is the supply voltage, VOUTx is VOUTP or VOUTN, Icell is the current from memory cell 1211 or 1221, and C is the capacitance of 1213 or 1223. Analog-to-digital converter 1230 will generate a digital output, DOUTx, in response to the difference between VOUTP and VOUTN. DOUTx is indicative of the value W.

FIG. 13 depicts differential verify circuit 1300 that can be controlled by algorithm controller 1114 in FIG. 11 to perform programming and verification method 1900 in FIG. 19. Differential verify circuit 1300 comprises ITV converter 1310 (a first circuit) coupled to W+ cell 1311, ITV converter 1320 (a second circuit) coupled to W− cell 1321, and analog-to-digital converter 1330. W+ cell 1311 stores a weight W+ and W− cell 1321 stores a weight W−. Together, W+ cell 1311 and W−1 cell 1321 store a weight, W, where W=(W+)−(W−). Differential verify circuit 1300 also comprises verify target circuit 1241 and comparison circuit 1240, which operate in the same manner described previously for FIG. 12 and generates output 1242 (VFY_Flag).

ITV converter 1310 comprises load resistor 1312, operational amplifier 1313, and NMOS transistor 1313, arranged as shown. ITV converter 1320 comprises load resistor 1322, operational amplifier 1323, and NMOS transistor 1324, arranged as shown.

During a read or verify operation, W+ cell 1211 will draw a current IBL+ that will cause a voltage drop across resistor 1312 such that the bottom terminal of resistor 1312 will have a voltage VOUTP, and W− cell 1221 will draw a current IBL− that will cause a voltage drop across resistor 1322 such that the bottom terminal of resistor 1322 will have a voltage, VOUTN. Analog-to-digital converter 1230 will generate a digital output, DOUTx, in response to the difference between VOUTP and VOUTN, according to the formula (Vdd−VOUTx)=(Icell*R), where Vdd is the supply voltage, VOUTx is VOUTP or VOUTN, Icell is the current from memory cell 1311 or 1311, and R is resistance of 1312 or 1322. DOUTx is indicative of the value W.

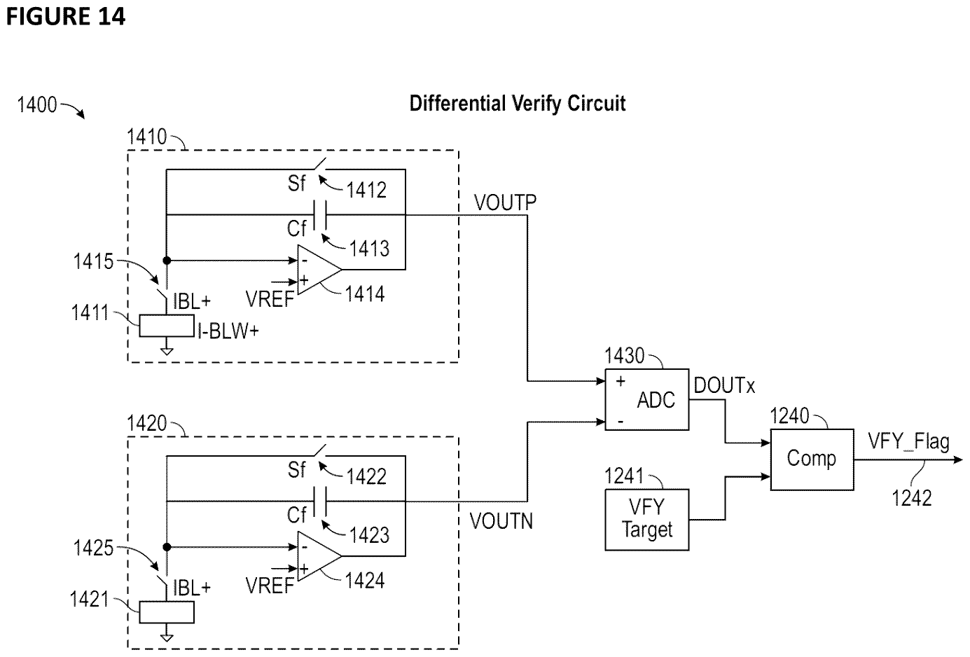

FIG. 14 depicts differential verify circuit 1400 that can be controlled by algorithm controller 1114 in FIG. 11 to perform programming and verification method 1900 in FIG. 19. Differential verify circuit 1400 comprises ITV converter 1410 (a first circuit) coupled to W+ cell 1411, ITV converter 1420 (a second circuit) coupled to W− cell 1421, and analog-to-digital converter 1430. W+ cell 1411 stores a weight W+ and W− cell 1421 stores a weight W−. Together, W+ cell 1411 and W−1 cell 1421 store a weight, W, where W=(W+)−(W−). Differential verify circuit 1400 also comprises verify target circuit 1241 and comparison circuit 1240, which operate in the same manner described previously for FIG. 12 and generates output 1242 (VFY_Flag).

ITV converter 1410 comprises switch 1412, switch 1415, capacitor 1413, and operational amplifier 1414, arranged as shown. ITV converter 1420 comprises switch 1422, switch 1425, capacitor 1423, and operational amplifier 1424, arranged as shown.

Prior to a read or verify operation, switches 1412, 1415, 1422, and 1425 are closed. This causes both terminals of capacitor 1413 to have the same voltage, VOUTP, which is equal to VREF, and both terminals of capacitor 1423 to have the same voltage, VOUTN, which is equal to VREF. During a read or verify operation, switches 1412 and 1422 are opened and switches 1415 and 1525 are closed for an integration time, Tint. During the time Tint, W+ cell 1411 will draw a current IBL+ that will cause the right plate of capacitor 1413 to charge up, which also causes VOUTP to increase, and W− cell 1421 will draw a current IBL− that will cause the right plate of capacitor 1423 to charge up, which also causes VOUTN to increase, according to the formula (VOUTx−VREF)=(Icell*Tint)/C, where VOUTx is VOUTP or VOUTN, Icell is the current from memory cell 1411 or 1421 and C is the capacitance of 1413 or 1423. Analog-to-digital converter 1430 will generate a digital output, DOUTx, in response to the difference between VOUTP and VOUTN. DOUTx is indicative of the value W.

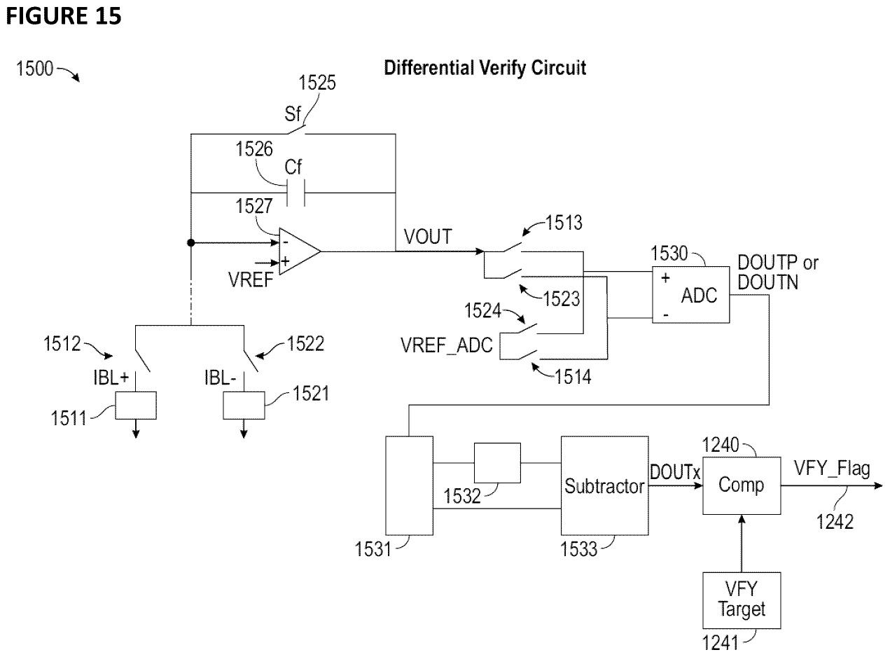

FIG. 15 depicts differential verify circuit 1500 that can be controlled by algorithm controller 1114 in FIG. 11 to perform programming and verification method 1900 in FIG. 19. Differential verify circuit 1500 comprises switches 1512, 1513, 1514, 1522, 1523, and 1524; switch 1525; capacitor 1526, operational amplifier 1527, analog-to-digital converter 1530 multiplexor 1531, latch 1532, and subtractor 1533. Differential verify circuit 1500 also comprises verify target circuit 1241 and comparison circuit 1240, which operate in the same manner described previously for FIG. 12 and generates output 1242 (VFY_Flag). Differential verify circuit 1500 is coupled to W+ cell 1511 and W− cell 1521. W+ cell 1511 stores a weight W+ and W− cell 1521 stores a weight W−. Together, W+ cell 1511 and W−1 cell 1521 store a weight, W, where W=(W+)−(W−).

During a first time period, t1, switch 1525 is closed. This causes both terminals of capacitor 1526 to have the same voltage, VOUT, which is equal to VREF.

During a second time period, t2, switch 1525 is opened, switches 1512, 1513, and 1514 are closed and switches 1522, 1523, and 1524 are opened. The switch 1512 is closed for an integration time, Tint. During this time Tint, W+ cell 1511 will draw a current IBL+ that will cause the right plate of capacitor 1526 to charge up, which also causes VOUT to increase. Analog-to-digital converter 1530 will generate a digital output, DOUTP, in response to the difference between VOUT and VREF_ADC, which is indicative of the value W+.

During a third time period, t3, switch 1525 is closed. This causes both terminals of capacitor 1526 to have the same voltage, VOUT, which is equal to VREF.

During a fourth time period, t4, switch 1525 is opened, switches 1512, 1513, and 1514 are opened and switches 1522, 1523, and 1524 are closed. The switch 1522 is closed for an integration time, Tint. During this time Tint, W− cell 1521 will draw a current IBL− that will cause the right plate of capacitor 1526 to charge up, which also causes VOUT to increase. Analog-to-digital converter 1530 will generate a digital output, DOUTN, in response to the difference between VOUT and VREF_ADC, which is indicative of the value W−.

The output of analog-to-digital converter is provided to multiplexor 1531, which receives a control signal during time period t2 to cause it to send the output (DOUTP) to latch 1532 and during time period t4 to cause it to send the output (DOUTN) to subtractor 1533. Latch 1532 holds the received value and outputs it to subtractor 1533. During time period t4 or thereafter, subtractor 1533 subtracts DOUTN from DOUTP to generate the output DOUTx, which is indicative of the value W.

Optionally, differential verify circuit 1500 can self-calibrate by injecting a bias current into the bitline (such as by connecting switch 1512 or 1522 to a current source during the self-calibration process) and trimming capacitor 1527 until VOUT is fully scaled, meaning that its maximum value is approximately equal to the maximum output that can be generated by analog-to-digital converter 1530.

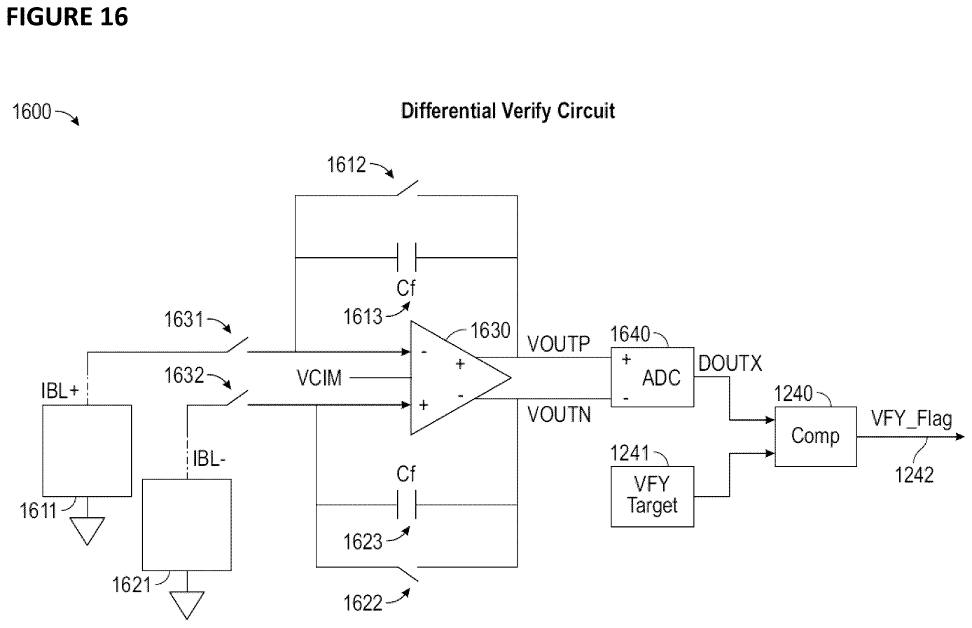

FIG. 16 depicts differential verify circuit 1600 that can be controlled by algorithm controller 1114 in FIG. 11 to perform programming and verification method 1900 in FIG. 19. Differential verify circuit 1600 comprises switches 1612, 1631, 1622, and 1632; capacitors 1613 and 1623; operational amplifier 1630; and analog-to-digital converter 1640, arranged as shown. The inverting input of operational amplifier 1630 is coupled to W+ cell 1611. W+ cell 1611 stores a weight W+ and W− cell 1621 stores a weight W−. Together, W+ cell 1611 and W−1 cell 1621 store a weight, W, where W=(W+)−(W−).

Prior to a read or verify operation, switches 1612, 1631, 1632, and 1622 are closed. This causes both terminals of capacitor 1613 to have the same voltage, VOUTP, which is equal to VREF, and both terminals of capacitor 1623 to have the same voltage, VOUTN, which is equal to VREF. During a read or verify operation, switches 1612 and 1622 are opened and switches 1631 and 1632 are closed for an integration time, Tint. During this time Tint, W+ cell 1611 will draw a current IBL+ that will cause the right plate of capacitor 1613 to charge up, which also causes VOUTP to increase. W− cell 1621 will draw a current IBL− that will cause the right plate of capacitor 1623 to charge up, which also causes VOUTN to increase. Operational amplifier 1630 outputs differential voltages VOUTP and VOUTN. Analog-to-digital converter 1640 will generate a digital output, DOUTx, in response to the difference between VOUTP and VOUTN. DOUTx is indicative of the value W.

Differential verify circuits 1200, 1300, 1400, 1500, and 1600 described in FIGS. 12, 13, 14, 15, and 16, respectively, can also be used for a read neural operation (such as during a neural network inference operation), meaning they can be used to digitize the difference in summation bitline currents where each bitline current is a sum of current drawn by all of the selected memory cells coupled to the bitline. In this instance, the W+ and W− cells depicted in FIGS. 12, 13, 14, 15, and 16 instead will be selected cells coupled to a first bit line and selected cells coupled to a second bit line, respectively.

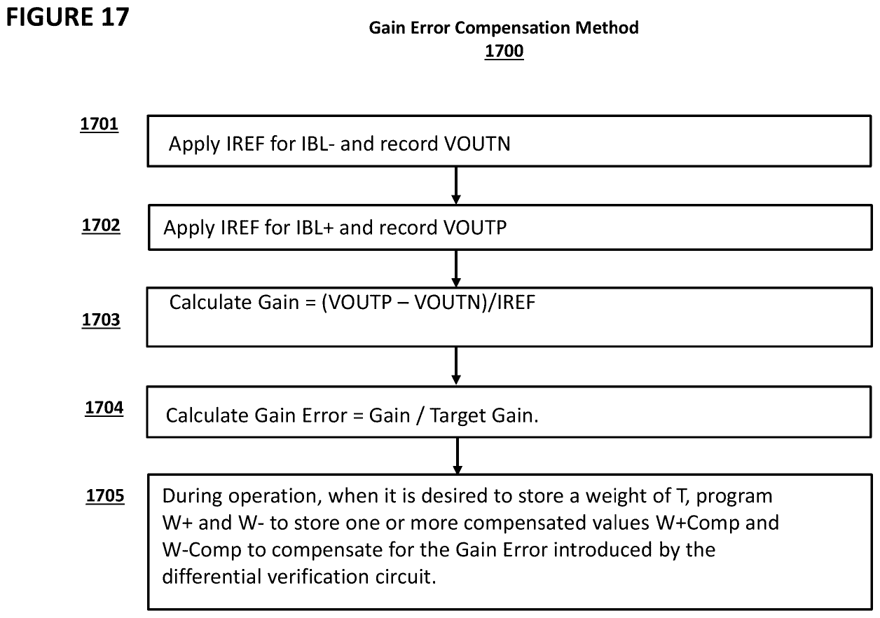

Differential verification circuits 1200, 1300, 1400, and 1600 in FIGS. 12, 13, 14, and 16, respectively, might introduce gain errors on top of the desired gain due to capacitance or resistance mismatch between the two capacitors or resistors or other factors. FIG. 17 depicts gain error compensation method 1700 to compensate for this gain error in differential verification circuits 1200, 1300, 1400, and 1600. Notably, differential verification circuit 1500 in FIG. 15 does not present this challenge since the same circuit is used for both the W+ and W− cells.

First, IREF is applied as a test current for IBL− and the resulting voltage VOUTN is recorded (1701).

Second, IREF is applied as a test current for IBL+ and the resulting voltage VOUTP is recorded (1702).

Third, Gain is calculated, where Gain=(VOUTP− VOUTN)/IREF (1703).

Fourth, Gain Error is calculated, where Gain Error=(Gain/Target Gain) (1704), where Target Gain is the desired gain of the differential verification circuit such as differential verification circuits 1200, 1300, 1400, and 1600.

Fifth, during operation, when it is desired to store a weight of T (meaning W=T), the W+ and W− cells are programed to store one or more compensated values W+ Comp and W− Comp to compensate for the Gain Error introduced by the differential verification circuit (1705). The compensation can be implemented in multiple different ways. For example, if the desired values for W+ and W− are W1 and W2, respectively, but a Gain Error is present in the circuit that affects the resulting VOUTP or VOUTN, then W+ Comp can be set to W1*(1−Gain Error), and W+ Comp and W− will be stored. Then during operation, the Gain Error will be completely or mostly offset. In this example, if Gain Error is 0.02, then W+ Comp will be 0.98W1; if Gain Error is −0.02, then W+ Comp will be 1.02W1.

Alternatively, W− Comp can be determined in a similar fashion and used and stored with W+. W− Comp can be set to W2*(1+Gain Error), and W+ and W− Comp will be stored. Then during operation, the Gain Error will be completely or mostly offset. In this example, if Gain Error is 0.02, then W− Comp will be 01.02W2; if Gain Error is −0.02, then W− Comp will be 0.98W2.

Thus, gain error compensation method 1700 compensates for the gain error present in a differential verification circuit by storing a scaled version of the desired weight, where the scaling factor is based on the gain error. Alternatively, the gain error can be adjusted (trimmed) by adjusting the load resistors or capacitors.

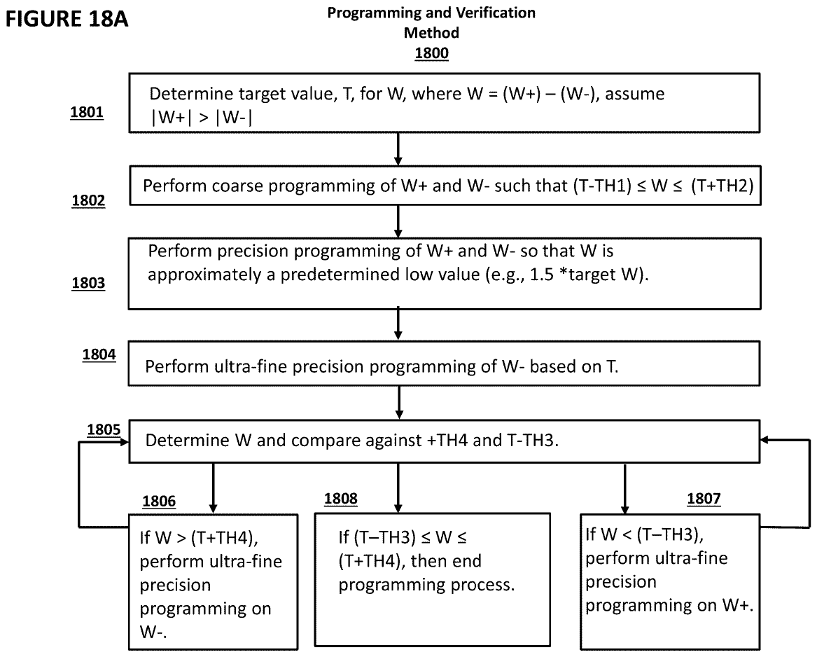

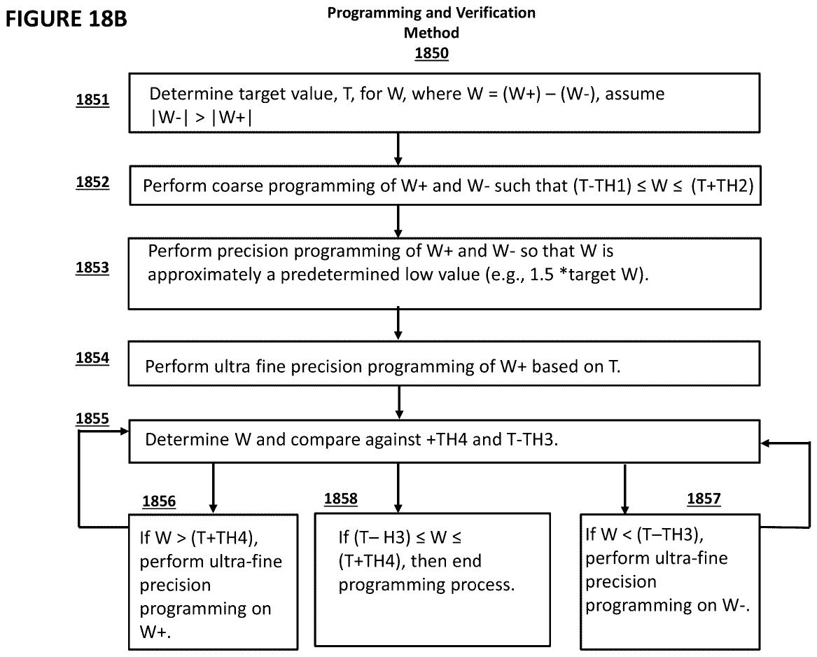

FIGS. 18A and 18B depict programming and verification methods 1800 and 1850, as will now be shown in FIGS. 18A and 18B, which are variations of programming and verification method 1900 in FIG. 19. Programming and verification methods 1800, 1850, and 1900 verify the differential value, W, without separately verifying the components W+ and W−, which can save many programming and verification cycles compared to prior art techniques, resulting in a much faster process for storing the desired value of W. It also results in much higher precision because the final tuning stage involves only one cell instead of two. It also allows overshoot recovery in a more efficient manner than was available previously.

Programming and verification methods 1800 and 1850 can be performed by a controller such as algorithm controller 1114 in VMM system 1100 in FIG. 11. The method of FIG. 18A is performed when |W+|>|W−|. The method of FIG. 18B is performed when |W+|<|W−|. Programming and verification methods 1800 and 1850 utilize coarse programming, precision programming, and ultra-fine precision programming, which are concepts previously disclosed by the assignee of the present application in U.S. Pat. No. 10,741,568, titled “Precision Tuning for the Programming of Analog Neural Memory in a Deep Learning Artificial Neural Network,” and U.S. Pat. No. 11,393,535, titled “Ultra-precise tuning of analog neural memory cells in a deep learning artificial neural network,” which are incorporated by reference herein. Precision programming alters the charge stored on a cell's floating gate in smaller increments than coarse programming, and ultra-fine precision programming alters the charge stored on a cell's floating gate in smaller increments than precision programming.

The steps of programming and verification method 1800 of FIG. 18A will now be described.

First, a target value, T, is determined for W to be stored in a differential pair of cells, W+ and W−, where W=(W+)−(W−). For example, the controller can consult a lookup table that has been pre-populated with target values, T, for each possible value of W that might be stored in a differential pair of cells (1801).

Second, coarse programming is performed on cells W+ and W− such that (T−TH1)≤W≤(T+TH2) (1802). TH1 and TH2 are coarse threshold values that are selected to ensure that W is within a certain range of values roughly near T. For example, if T=90, then TH1 and TH2 might be selected to be 5 so that at the end of step 1802, 85≤W≤95.

Third, precision programming is performed on W+ and W− so that W is approximately a predetermined low value (e.g., 1.5*the target W that might be stored in a differential pair of cells) (1803).

Fourth, ultra-fine precision programming is performed on W-based on T (1804).

Fifth, W is determined and compared against T+TH4 and T−TH3 using differential verify circuits 1200, 1300, 1400, 1500, 1600, or another differential verify circuit (1805).

If W>(T+TH4), ultra-fine precision programming is performed on W− and the process returns to 1805 (1806). TH4 is a predetermined threshold, for example 0.5-2% of W.

If W<(T−TH3), then an overshoot occurred (meaning that W+ was overprogrammed), in which case ultra-fine precision programming is performed on W+ and the process returns to 1805 (1807). TH3 is a predetermined threshold, for example 0.5-2% of W. By contrast, in a prior art system when an overshoot occurred, it was necessary to erase the cell that was overprogrammed and to start the programming process over. Programming and verification method 1800 enables the system to compensate for an overprogramming of the W+ cell by performing ultra-fine precision programming on the W− cell to achieve the desired value of W.

If (T−TH3)≤W< (T+TH4), then W is close enough to T with acceptable thresholds above and below T and the process ends (1808).

The steps of programming and verification method 1850 of FIG. 18B will now be described.

First, a target value, T, is determined for W to be stored in a differential pair of cells, W+ and W−, where W=(W+)−(W−). For example, the controller can consult a lookup table that has been pre-populated with target values, T, for each possible value of W that might be stored in a differential pair of cells (1851).

Second, coarse programming is performed on cells W+ and W− such that (T−TH1)≤W≤(T+TH2) (1852). TH1 and TH2 are coarse threshold values that are selected to ensure that W is within a certain range of values roughly near T. For example, if T=90, then TH1 and TH2 might be selected to be 5 so that at the end of step 1852, 85≤W≤95.

Third, precision programming is performed on W+ and W− so that W is approximately a predetermined low value (e.g., 1.5*the target W that might be stored in a differential pair of cells) (1853).

Fourth, ultra-fine precision programming is performed on W+ based on T (1854).

Fifth, W is determined and compared against T+TH4 and T−TH3 using differential verify circuits 1200, 1300, 1400, 1500, 1600, or another differential verify circuit (1855).

If W>(T+TH4), ultra-fine precision programming is performed on W+ and the process returns to 1855 (1856). TH4 is a predetermined threshold, for example 0.5-2% of W.

If W<(T−TH3), then an overshoot occurred (meaning that W− was overprogrammed), in which case ultra-fine precision programming is performed on W− and the process returns to 1855 (1857). TH3 is a predetermined threshold, for example 0.5-2% of W. By contrast, in a prior art system when an overshoot occurred, it was necessary to erase the cell that was overprogrammed and to start the programming process over. Programming and verification method 1800 enables the system to compensate for an overprogramming of the W− cell by performing ultra-fine precision programming on the W+ cell to achieve the desired value of W.

If (T−TH3)≤W≤(T+TH4), then W is close enough to T with acceptable thresholds above and below T and the process ends (1858).

Table No. 5 contains example values for T, W, W+, and W− during programming and verification methods 1800:

TABLE No 5
Examples Values During
Programming and Verification Method 1800

| | | |
|---|---|---|
| W | W+ | W− |

T = 96

| | | | |
|---|---|---|---|
| Result after | 10 | 154 | 144 |
| 1802 | | | |
| Result after | 149.5 | 154 | 4.5 |
| 1803 | | | |
| Result after | 94 | 98.5 | 4.5 |
| 1804 | | | |
| Result after | 96 | 98.5 | 2.5 |
| 1808 | | | |

T = 48

| | | | |
|---|---|---|---|
| Result after | 10 | 82 | 72 |
| 1802 | | | |
| Result after | 77 | 82 | 5 |
| 1803 | | | |
| Result after | 46 | 51 | 5 |
| 1804 | | | |
| Result after | 48.5 | 51 | 2.5 |
| 1808 | | | |

T = 3

| | | | |
|---|---|---|---|
| Result after | 10 | 14.5 | 4.5 |
| 1802 | | | |
| Result after | 10 | 14.5 | 4.5 |
| 1803 | | | |
| Result after | 2 | 7 | 5 |
| 1804 | | | |
| Result after | 3 | 7 | 4 |
| 1808 | | | |

It should be noted that, as used herein, the terms “over” and “on” both inclusively include “directly on” (no intermediate materials, elements, or space disposed therebetween) and “indirectly on” (intermediate materials, elements, or space disposed therebetween). Likewise, the term “adjacent” includes “directly adjacent” (no intermediate materials, elements, or space disposed therebetween) and “indirectly adjacent” (intermediate materials, elements, or space disposed therebetween), “mounted to” includes “directly mounted to” (no intermediate materials, elements, or space disposed therebetween) and “indirectly mounted to” (intermediate materials, elements, or spaced disposed therebetween), and “electrically coupled” includes “directly electrically coupled to” (no intermediate materials or elements therebetween that electrically connect the elements together) and “indirectly electrically coupled to” (intermediate materials or elements therebetween that electrically connect the elements together). For example, forming an element “over a substrate” can include forming the element directly on the substrate with no intermediate materials/elements therebetween, as well as forming the element indirectly on the substrate with one or more intermediate materials/elements therebetween.

What is claimed is:

1. A circuit comprising:
a first circuit coupled to a first non-volatile memory cell to generate a first voltage in response to a first value stored in the first non-volatile memory cell;
a second circuit coupled to a second non-volatile memory cell to generate a second voltage in response to a second value stored in the second non-volatile memory cell;
a differential analog-to-digital converter to generate a digital value in response to a difference between the first voltage and the second voltage; and
a comparator to determine whether the digital value is near a target value within a threshold.

2. The circuit of claim 1, wherein the first circuit comprises a first capacitor and the first voltage is generated by the first capacitor in response to current drawn by the first non-volatile memory cell and the second circuit comprises a second capacitor and the second voltage is generated by the second capacitor in response to current drawn by the second non-volatile memory cell.

3. The circuit of claim 2, wherein the first circuit comprises a first operational amplifier and the second circuit comprises a second operational amplifier.

4. The circuit of claim 2, the circuit comprising a differential operational amplifier, wherein the first capacitor is coupled to an inverting input of the differential operational amplifier and to an output of the differential operational amplifier and the second capacitor is coupled to a non-inverting input of the differential operational amplifier and to the output of the differential operational amplifier.

5. The circuit of claim 1, wherein the first circuit comprises a first resistor and the first voltage is generated by current drawn through the first resistor by the first non-volatile memory cell and the second circuit comprises a second resistor and the second voltage is generated by current drawn through the second resistor by the second non-volatile memory cell.

6. The circuit of claim 5, wherein the first circuit comprises a first operational amplifier and the second circuit comprises a second operational amplifier.

7. The circuit of claim 1, wherein the first value is a W+ weight and the second value is a W− weight.

8. The circuit of claim 1, wherein the first non-volatile memory cell and the second non-volatile memory cell are split-gate flash memory cells.

9. The circuit of claim 1, wherein the first non-volatile memory cell and the second non-volatile memory cell are stacked-gate flash memory cells.

10. A circuit comprising:
a current-to-voltage converter selectively coupled to a first non-volatile memory cell during a first time period to generate a first voltage and to a second non-volatile memory cell during a second time period to generate a second voltage; and
a circuit to generate a digital value in response to a difference between the first voltage and the second voltage.

11. The circuit of claim 10, wherein the current-to-voltage converter comprises:
a first switch coupled between a first node and a second node;
a capacitor coupled between the first node and the second node; and
an operational amplifier comprising an inverting input coupled to the first node, a non-inverting input receiving a reference voltage, and an output coupled to the second node.

12. The circuit of claim 11, wherein the first node is coupled to the first non-volatile memory cell by a second switch during the first time period and to the second non-volatile memory cell by a third switch during the second time period.

13. A method of overshoot recovery in programming and verification of a differential pair of non-volatile memory cells comprising a first non-volatile memory cell and a second non-volatile memory cell, the method comprising:
determining a target value for the differential pair of non-volatile memory cells;
performing programming operations on the first non-volatile memory cell;
performing programming operations on the second non-volatile memory cell; and
when a difference between a value stored in the first non-volatile memory cell and a value stored in the second non-volatile memory cell is less than the target value by a threshold value, performing precision programming on the second non-volatile memory cell.

14. The method of claim 13, wherein the precision programming changes a value of the second non-volatile memory cell in smaller increments than the programming operations on the second non-volatile memory cell.

15. A method of programming and verification of a differential pair of non-volatile memory cells comprising a first non-volatile memory cell and a second non-volatile memory cell, the method comprising:
determining a target value for the differential pair of non-volatile memory cells;
performing programming operations on the first non-volatile memory cell;
performing programming operations on the second non-volatile memory cell; and
performing precision programming on the non-volatile memory cell storing the lower value among the first non-volatile memory cell and the second non-volatile memory cell.

16. The method of claim 15, wherein the precision programming changes a value of the non-volatile memory cell storing the lower value in smaller increments than the programming operations on the non-volatile memory cell storing the lower value among the first non-volatile memory cell and the second non-volatile memory cell.

17. A method of programming and verifying a differential value comprising:
programming a first non-volatile memory cell to store a first value, W+;
programming a second non-volatile memory cell to store a second value, W−; and
verifying that the value W is within a predetermined threshold of a target value, where W=(W+)−(W−).

18. The method of claim 17, wherein if the value W is not within a predetermined threshold of a target value: (i) programming one of the first non-volatile memory cell and the second non-volatile memory cell, and (ii) verifying that the value W is within the predetermined threshold of the target value.

19. A method of performing gain error compensation in a differential verify circuit, the method comprising:
applying a reference current to a first input of the differential verify circuit to generate a first voltage;
applying the reference current to a second input of the differential verify circuit to generate a second voltage;
determining a gain equal to a first value divided by a second value, wherein the first value is the second voltage minus the first voltage and the second value is the reference current;
determining a gain error equal to the gain divided by a target gain; and
programming a pair of non-volatile memory cells to store a differential value equal to a target weight comprising compensation for the gain error.

20. The method of claim 19 wherein the pair of non-volatile memory cells are split-gate flash memory cells.

21. The method of claim 19, wherein the pair of non-volatile memory cells are stacked-gate flash memory cells.
